(19) United States
(12) Patent Application Publication
(10) Pub. No.: US 2017/0174807 A1
(43) Pub. Date: Jun. 22, 2017

(54) POLYMER, PHOTOSENSITIVE RESIN COMPOSITION, AND ELECTRONIC DEVICE

(71) Applicant: SUMITOMO BAKELITE CO., LTD., Tokyo (JP)

(72) Inventors: Osamu ONISHI, Tokyo (JP); Haruo IKEDA, Tokyo (JP)

(73) Assignee: SUMITOMO BAKELITE CO., LTD., Tokyo (JP)

(21) Appl. No.: 15/302,152

(22) PCT Filed: Mar. 10, 2015
(86) PCT No.: PCT/JP2015/057028

§ 371 Date: Oct. 5, 2016

(30) Foreign Application Priority Data
Mar. 20, 2014 (JP) 2014-058123

(51) Int. Cl. C08F 222/40; C08G 61/08; G03F 7/038; C08G 61/04

(52) U.S. Cl. CPC C08F 222/40; C08G 61/04; C08G 61/08; G03F 7/038

(57) ABSTRACT

Provided is a polymer including a structural unit represented by the following Formula (1a); and a structural unit represented by the following Formula (1b).

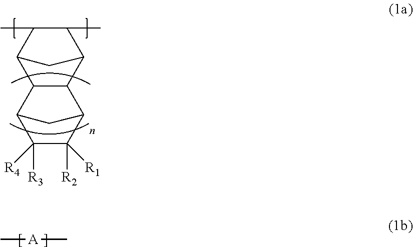

(In Formula (1a), n represents 0, 1, or 2. R₁, R₂, R₃, and R₄ each independently represent hydrogen or an organic group having 1 to 10 carbon atoms, at least one of R₁, R₂, R₃, and R₄ including an oxetane ring.)

### TECHNICAL FIELD

The present invention relates to a polymer, a photosensitive resin composition, and an electronic device.

### BACKGROUND ART

A resin film obtained by exposing a photosensitive resin composition is occasionally used as an insulating film constituting an electronic device. As a technique related to such a photosensitive resin composition, techniques described in Patent Document 1 may be exemplified. Patent Document 1 describes a radiation-sensitive resin composition containing a copolymer which includes a polymerization unit of unsaturated carboxylic acid and a polymerization unit of a specific compound, a 1,2-quinonediazide compound, and a latent acid-generating agent.

### RELATED DOCUMENT

### Patent Document

[Patent Document 1] Japanese Laid-open Patent Application Publication No. H9(1997)-230596

### SUMMARY OF THE INVENTION

In recent years, there has been a demand for development of a new polymer which is capable of improving reliability of a material used in a process of producing an electronic device.

According to the present invention, there is provided a polymer including: a structural unit represented by the following Formula (1a); and a structural unit represented by the following Formula (1b).

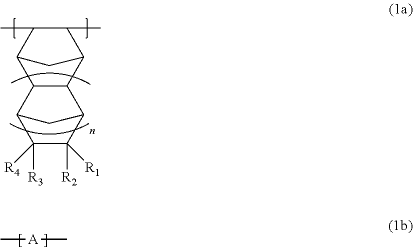

(In Formula (1a), n represents 0, 1, or 2. R₁, R₂, R₃, and R₄ each independently represent hydrogen or an organic group having 1 to 10 carbon atoms, at least one of R₁, R₂, R₃, and R₄ including an oxetane ring. “A” represents a structural unit represented by the following Formula (3), (4), (5), or (6).)

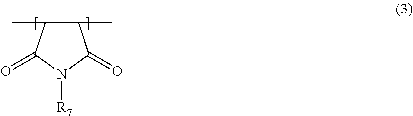

(In Formula (3), R₇ represents hydrogen, an alkyl group having 1 to 12 carbon atoms, or a cycloalkyl group having 3 to 8 carbon atoms.)

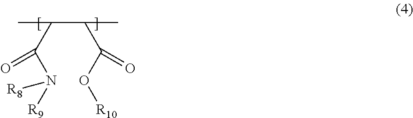

(In Formula (4), R₈, R₉, and R₁₀ each independently represent hydrogen, an alkyl group having 1 to 12 carbon atoms, or a cycloalkyl group having 3 to 8 carbon atoms.)

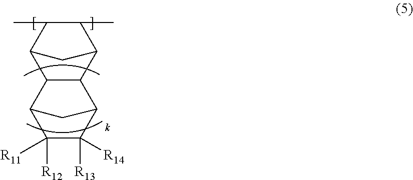

(In Formula (5), k represents 0, 1, or 2, and R₁₁, R₁₂, R₁₃, and R₁₄ each independently represent hydrogen or an organic group having 1 to 10 carbon atoms.)

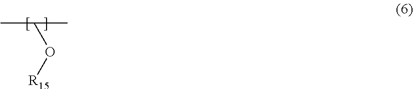

(In Formula (6), R₁₅ represents an organic group having 1 to 10 carbon atoms.)

Further, according to the present invention, there is provided a photosensitive resin composition which is used for forming a permanent film, including the above-described polymer.

Furthermore, according to the present invention, there is provided an electronic device including a permanent film formed from the above-described photosensitive resin composition.

According to the present invention, it is possible to provide a new polymer which is capable of improving reliability of a material used in a process of producing an electronic device.

### BRIEF DESCRIPTION OF THE DRAWINGS

The above-described and other objects, features, and advantages will become more apparent with reference to preferred embodiments described below and the accompanying drawing.

FIG. 1 is a sectional view showing an example of an electronic device.

### DESCRIPTION OF EMBODIMENTS

Hereinafter, embodiments will be described with reference to the accompanying drawing. In addition, in the drawing, the same constituent elements are denoted by the same reference numerals and the description thereof will not be repeated.

A polymer (first polymer) according to the present embodiment includes a structural unit represented by the following Formula (1a) and a structural unit represented by the following Formula (1b).

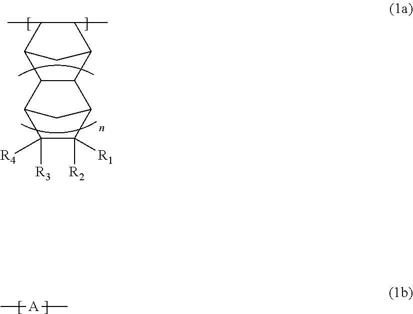

(In Formula (1a), n represents 0, 1, or 2. R₁, R₂, R₃, and R₄ each independently represent hydrogen or an organic group having 1 to 10 carbon atoms, at least one of R₁, R₂, R₃, and R₄ including an oxetane ring. A represents a structural unit represented by the following Formula (3), (4), (5), or (6).)

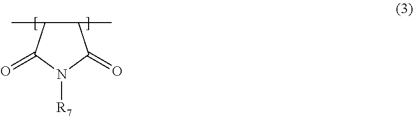

(In Formula (3), R₇ represents hydrogen, an alkyl group having 1 to 12 carbon atoms, or a cycloalkyl group having 3 to 8 carbon atoms.)

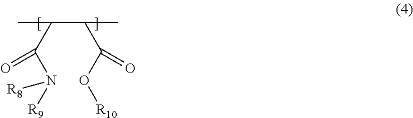

(In Formula (4), R₈, R₉, and R₁₀ each independently represent hydrogen, an alkyl group having 1 to 12 carbon atoms, or a cycloalkyl group having 3 to 8 carbon atoms.)

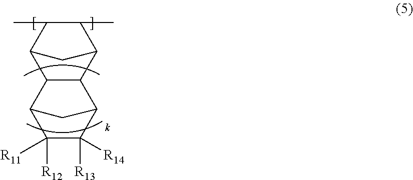

(In Formula (5), k represents 0, 1, or 2, and R₁₁, R₁₂, R₁₃, and R₁₄ each independently represent hydrogen or an organic group having 1 to 10 carbon atoms.)

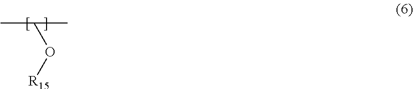

(In Formula (6), R₁₅ represents an organic group having 1 to 10 carbon atoms.)

A process margin may be exemplified as a measure for determining reliability of a material used in a process of producing an electronic device. The process margin indicates a permissible range of deviation in alignment resulting from various devices or processes, and an effect of post-exposure delay during the processes of exposure to development on a pattern dimension may be exemplified as a cause of the deviation. Particularly, since a photosensitive resin composition used to form a permanent film such as an interlayer insulating film includes a polymerizable group, there is a concern of a curing reaction advancing during the post-exposure delay as a result of a catalytic action by an acid or an alkali present during the processes, causing a problem such as residues remaining at the time when rework is needed. As a result, since such a problem also affects the yield of an electronic device, there is a demand for development of a new polymer which is capable of achieving a photosensitive resin composition having excellent reworkability and a wide process margin.

The present inventors have conducted intensive research on a new polymer having excellent reworkability. As a result, the present inventors have newly developed a first polymer having a structural unit represented by the above-described Formula (1a) and a structural unit represented by the above-described Formula (1b). As such, according to the present embodiment, it is possible to provide a new polymer with improved reliability capable of widening the process margin for the process of producing an electronic device.

Hereinafter, the first polymer, the photosensitive resin composition, and the electronic device will be described in detail.

(First Polymer)

First, the first polymer will be described.

As described above, the first polymer according to the present embodiment is configured of a copolymer having a structural unit represented by the following Formula (1a) and a structural unit represented by the following Formula (1b).

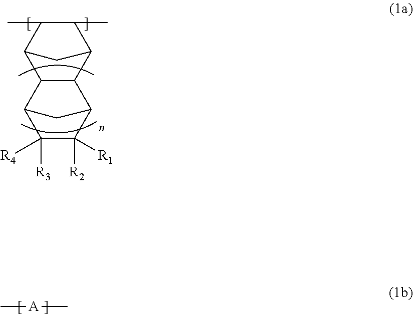

In Formula (1a), n represents 0, 1, or 2. R₁, R₂, R₃, and R₄ each independently represent hydrogen or an organic group having 1 to 10 carbon atoms, at least one of R₁, R₂, R₃, and R₄ including an oxetane ring. “A” represents a structural unit represented by the following Formula (3), (4), (5), or (6). The molar ratio of the structural unit represented by Formula (1a) is not particularly limited, but is particularly preferably equal to or greater than 10 and equal to or less than 90 based on 100 of the total first polymer. The molar ratio of the structural unit represented by Formula (1b) is not particularly limited, but is particularly preferably equal to or greater than 10 and equal to or less than 90 based on 100 of the total first polymer.

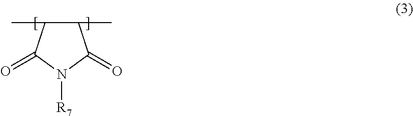

(In Formula (3), R₇ represents hydrogen, an alkyl group having 1 to 12 carbon atoms, or a cycloalkyl group having 3 to 8 carbon atoms.)

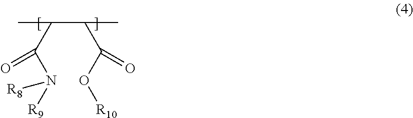

(In Formula (4), R₈, R₉, and R₁₀ each independently represent hydrogen, an alkyl group having 1 to 12 carbon atoms, or a cycloalkyl group having 3 to 8 carbon atoms.)

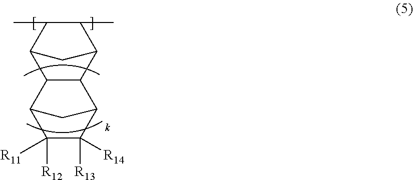

(In Formula (5), k represents 0, 1, or 2, and R₁₁, R₁₂, R₁₃, and R₁₄ each independently represent hydrogen or an organic group having 1 to 10 carbon atoms.)

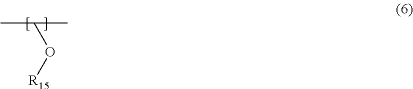

(In Formula (6), R₁₅ represents an organic group having 1 to 10 carbon atoms.)

The above-described copolymer may include one or two or more of the respective structural units represented by the above-described Formulae (3), (4), (5), and (6) as A. According to such a structure, facilitated adjustment may be achieved for various properties such as reworkability, lithographic performance, solvent resistance, transmittance, and strength of a resin film formed using the photosensitive resin composition that includes the first polymer. In the present embodiment, the above-described properties and performance can be adjusted by appropriately selecting a structural unit included in the copolymer as “A”.

In the present embodiment, from the viewpoint of improving the balance among the reworkability, solvent resistance, and temporal stability, it is particularly preferable that the copolymer includes two or more kinds from respective structural units represented by the above-described Formulae (3), (4), (5), and (6) as “A”.

Moreover, in a case where a plurality of structural units represented by the above-described Formula (1a) are present in the copolymer, the structures of the respective structural units represented by the above-described Formula (1a) can be independently determined. Further, in a case where a plurality of structural units represented by the above-described Formula (3) as “A” are present in the copolymer, the structures of the respective structural units represented by the above-described Formula (3) can be independently determined. The same applies to each of the structural unit represented by the above-described Formula (4), the structural unit represented by Formula (5), and the structural unit represented by Formula (6).

In the above-described Formula (1a), at least one of R₁, R₂, R₃, and R₄ represents a C1-C10 organic group which has an oxetane ring. Examples of the organic group having an oxetane ring include groups represented by the following Formula (7).

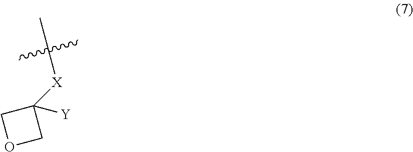

In Formula (7), X represents a single bond or a divalent organic group having 1 to 6 carbon atoms and Y represents hydrogen or an alkyl group having 1 to 7 carbon atoms. The divalent organic group constituting X is a linear or branched divalent hydrocarbon group which may have one or two or more kinds selected from oxygen, nitrogen, and silicon. Among these, a group including one or more linking groups such as an amino group (—NR—), an amide bond (—NHC(═O)—), an ester bond (—C(═O)—O—), a carbonyl group (—C(═O)—), or an ether bond (—O—) in the main chain is more preferable and a group including one or more linking groups such as an ester bond, a carbonyl group, or an ether bond in the main chain is particularly preferable. Further, one or more hydrogen atoms contained in the organic group constituting X may be substituted with a halogen atom such as fluorine, chlorine, bromine, or iodine. Moreover, examples of the alkyl group constituting Y include a methyl group, an ethyl group, an n-propyl group, an isopropyl group, an n-butyl group, an isobutyl group, a sec-butyl group, a tert-butyl group, a pentyl group, a neopentyl group, a hexyl group, and a heptyl group. In addition, one or more hydrogen atoms contained in the alkyl group constituting Y may be substituted with a halogen atom such as fluorine, chlorine, bromine, or iodine.

In the present embodiment, it is more preferable that the above-described organic group having an oxetane ring is an organic group represented by the following Formula (8) or an organic group represented by the following Formula (9). Accordingly, it is possible to more effectively improve the reworkability, temporal stability, and solvent resistance of the photosensitive resin composition.

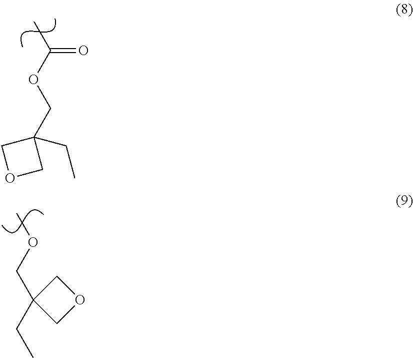

Examples of an organic group which constitutes R₁, R₂, R₃, and R₄ with 1 to 10 carbon atoms and no oxetane ring include an alkyl group, an alkenyl group, an alkynyl group, an alkylidene group, an aryl group, an aralkyl group, an alkaryl group, a cycloalkyl group, and a heterocyclic group other than an oxetane group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Examples of the alkenyl group include an allyl group, a pentenyl group, and a vinyl group. Examples of the alkynyl group include an ethynyl group. Examples of the alkylidene group include a methylidene group and an ethylidene group. Examples of the aryl group include a phenyl group and a naphthyl group. Examples of the aralkyl group include a benzyl group and a phenethyl group. Examples of the alkaryl group include a tolyl group and a xylyl group. Examples of the cycloalkyl group include an adamantyl group, a cyclopentyl group, a cyclohexyl group, and a cyclooctyl group. Examples of the heterocyclic group include an epoxy group. Further, in the alkyl group, the alkenyl group, the alkynyl group, the alkylidene group, the aryl group, the aralkyl group, the alkaryl group, the cycloalkyl group, and the heterocyclic group, one or more hydrogen atoms may be substituted with a halogen atom such as fluorine, chlorine, bromine, or iodine.

In the present embodiment, from the viewpoint of improving the reworkability, temporal stability, and solvent resistance, it is particularly preferable that any one of R₁, R₂, R₃, and R₄ represents an organic group having an oxetane ring and the rest represents hydrogen. Here, the organic groups exemplified above can be applied as the organic group having an oxetane ring.

Examples of the alkyl group constituting R₇ and having 1 to 12 carbon atoms include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, a decyl group, an undecyl group, and a dodecyl group. Further, examples of the cycloalkyl group constituting R₇ and having 3 to 8 carbon atoms include a cyclopropyl group, a cyclobutyl group, a cyclopentyl group, a cyclohexyl group, a cycloheptyl group, and a cyclooctyl group. In addition, one or more hydrogen atoms included in R₇ may be substituted with a halogen atom such as fluorine, chlorine, bromine, or iodine.

Examples of the alkyl group constituting R₈, R₉, and R₁₀ and having 1 to 12 carbon atoms include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, a decyl group, an undecyl group, and a dodecyl group. Further, examples of the cycloalkyl group constituting R₈, R₉, and R₁₀ and having 3 to 8 carbon atoms include a cyclopropyl group, a cyclobutyl group, a cyclopentyl group, a cyclohexyl group, a cycloheptyl group, and a cyclooctyl group. In addition, one or more hydrogen atoms included in R₈, R₉, and R₁₀ may be substituted with a halogen atom such as fluorine, chlorine, bromine, or iodine.

In the present embodiment, from the viewpoint of improving developability and reworkability, it is particularly preferable that the structural unit represented by the above-described Formula (4) is represented by the following Formula (4-1).

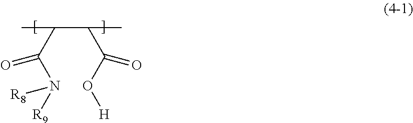

Examples of the C1-C10 organic group which constitutes R₁₁, R₁₂, R₁₃, and R₁₄ include an organic group containing a glycidyl group or a carboxyl group and an alkyl group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Further, examples of the organic group containing a glycidyl group or a carboxyl group include the following. Further, one or more hydrogen atoms included in R₁₁, R₁₂, R₁₃, and R₁₄ may be substituted with a halogen atom such as fluorine, chlorine, bromine, or iodine.

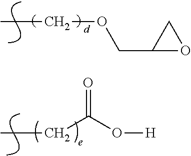

(In the formula, d and e represent an integer of 0 to 5.)

Examples of the C 1-C10 organic group which constitutes R₁₅ include an organic group containing a glycidyl group or an oxetane group and an alkyl group. Examples of the alkyl group include a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group. Further, examples of the organic group containing a glycidyl group or an oxetane group include the following. Further, one or more hydrogen atoms included in R₁₅ may be substituted with a halogen atom such as fluorine, chlorine, bromine, or iodine.

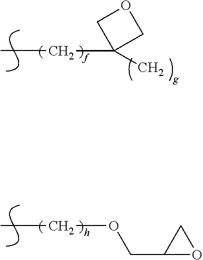

(In the formula, f, g, and h represent an integer of 0 to 5.)

Further, the copolymer constituting the first polymer may include structural units other than the structural unit represented by the above-described Formula (1a) and the structural unit represented by the above-described Formula (1b) within the range not inhibiting the effects of the present invention.

Examples of the first polymer according to the present embodiment may include the following. Moreover, the first polymer is not limited to those described below.

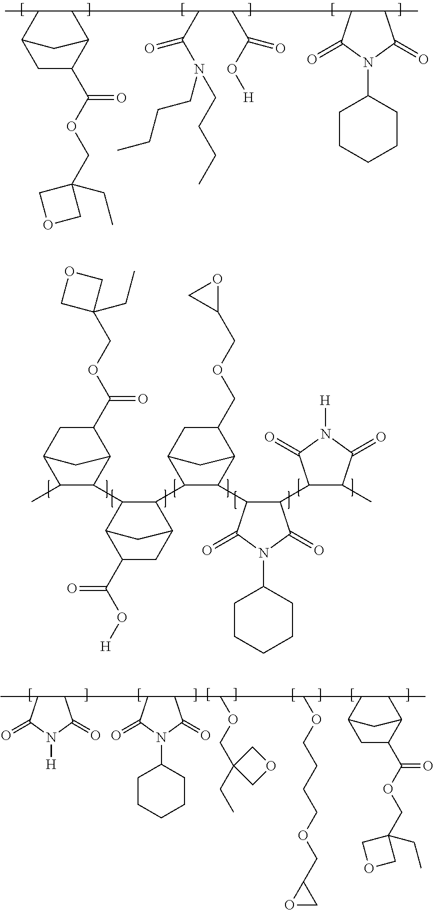

In addition, the first polymer may include, as a low molecular weight component, monomers represented by the following Formulae (10), (11), (12), and (13), and one or two or more kinds of maleic anhydrides.

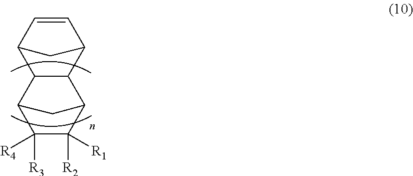

(In Formula (10), n, R₁, R₂, R₃, and R₄ may represent those exemplified in the above-described Formula (1a).)

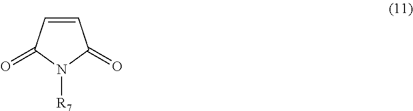

(In Formula (11), R₇ may represent any one of those exemplified in the above-described Formula (3).)

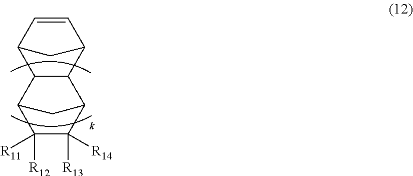

(In Formula (12), k, R₁₁, R₁₂, R₁₃, and R₁₄ may represent those exemplified in the above-described Formula (5).)

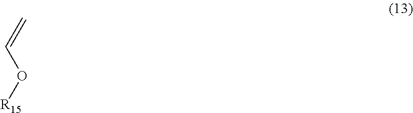

(In Formula (13), R₁₅ may represent any one of those exemplified in the above-described Formula (6).)

The first polymer can be synthesized, for example, in the following manner.

(Polymerization Step (Process S1))

First, an oxetane group-containing norbornene type monomer represented by the above-described Formula (10) and another monomer are prepared. As the other monomer, one or two or more kinds selected from maleic anhydride, a maleimide type monomer represented by the above-described Formula (11), a norbornene type monomer represented by the above-described Formula (12), and a vinyl ether type monomer represented by the above-described Formula (13) can be used.

The oxetane group-containing norbornene type monomer represented by the above-described Formula (10) can be obtained by reacting an oxetane compound with cyclopentadiene generated by cracking dicyclopentadiene through heating. As the oxetane compound, for example, acrylic oxetane such as (3-ethyloxetan-3-yl)methyl acrylate or oxetane vinyl ether such as ethyl oxetane methyl vinyl ether can be used. Moreover, cracking is particularly preferably performed in the presence of liquid paraffin, since this allows to dissolve by-products while lowering the melting point of dicyclopentadiene.

Next, the oxetane group-containing norbornene type monomer represented by the above-described Formula (10) and the above-described other monomer are subjected to additional polymerization, thereby obtaining a copolymer (copolymer 1) of these monomers. Here, the addition polymerization is performed through, for example, radical polymerization. In the present embodiment, solution polymerization can be performed by, for example, dissolving the oxetane group-containing norbornene type monomer represented by the above-described Formula (10), the above-described other monomer, and a polymerization initiator in a solvent and heating the solution for a predetermined time. At this time, the heating temperature can be set to 50° C. to 80° C., for example. Moreover, the heating time can be set to 1 to 20 hours, for example. Further, it is more preferable that the solution polymerization is performed after dissolved oxygen in the solvent is removed by nitrogen bubbling.

Further, a molecular weight regulator or a chain transfer agent can be used as needed. Examples of the chain transfer agent may include thiol compounds such as dodecyl mercaptan, mercaptoethanol, and 4,4-bis(trifluoromethyl)-4-hydroxy-1-mercaptobutane. These chain transfer agents may be used alone or in combination of two or more kinds thereof.

As the solvent used in the solution polymerization, one or two or more kinds selected from methyl ethyl ketone (MEK), propylene glycol monomethyl ether, diethyl ether, tetrahydrofuran (THF), and toluene can be used. Further, as the polymerization initiator, one or two or more kinds selected from an azo compound and an organic peroxide can be used. Examples of the azo compound include azobisisobutyronitrile (AIBN), dimethyl 2,2′-azobis(2-methylpropionate), and 1,1′-azobis(cyclohexanecarbonitrile) (ABCN). Examples of the organic peroxide include hydrogen peroxide, ditertiary butyl peroxide (DTBP), benzoyl peroxide (BPO), and methyl ethyl ketone peroxide (MEKP).

(Ring-Opening Step (Process S2))

In a case of obtaining a copolymer that includes a structural unit represented by the above-described Formula (4), for example, the above-described polymerization step (process Si) is performed using a monomer including maleic anhydride as the other monomer, and then the step (process S2) of subjecting a structural unit derived from maleic anhydride to ring-opening can be performed.

The structural unit represented by the above-described Formula (4) can be obtained by subjecting, for example, a structural unit derived from maleic anhydride to ring-opening using amines exemplified in primary amines and secondary amines such as dibutylamine. This process is performed by dissolving the copolymer 1 obtained by carrying out, for example, the above-described polymerization step (process S1) in an organic solvent such as methyl ethyl ketone, adding amines thereto, and heating the solution in a temperature range of 50° C. to 80° C. for 1 hour to 10 hours.

(Washing Step (Process S3))

The reaction solution including the copolymer 1 obtained in the above-described manner is added to hexane or methanol so that a polymer is precipitated. Next, the polymer is filtered off, washed with hexane, methanol, or the like, and dried. Further, in order to remove unreacted amines, neutralization or a water-washing process may be further performed. In the present embodiment, the first polymer can be synthesized in the above-described manner.

(Photosensitive Resin Composition)

A photosensitive resin composition is used to form a permanent film.

The above-described permanent film is formed of a resin film obtained by curing a photosensitive resin composition. In the present embodiment, for example, a coating film formed of a photosensitive resin composition is patterned to have a desired shape through exposure and development and then cured by carrying out a heat treatment or the like, thereby obtaining a permanent film.

As the permanent film formed using a photosensitive resin composition, an interlayer film, a surface protective film, or a dam material may be exemplified. The applications of the permanent film are not limited thereto.

The interlayer film indicates an insulating film provided in the multilayer structure and the type thereof is not particularly limited. Examples of the applications of the interlayer film include use in semiconductors, for example, as an interlayer insulating film constituting a multilayer wiring structure of a semiconductor element, and a film used in a build-up layer or a core layer constituting a circuit board, and moreover, use in display devices, for example, as a planarization film covering a thin film transistor (TFT) in a display device, a liquid crystal alignment film, a projection provided on a color filter substrate of a multi domain vertical alignment (MVA) type liquid crystal display device, and a partition wall for forming a cathode of an organic EL element.

The surface protective film is formed on the surface of an electronic component or an electronic device and indicates an insulating film used for protecting the surface of the component or device, the type thereof being not particularly limited. Examples of such a surface protective film include a passivation film or a buffer coat layer provided on a semiconductor element, and a cover coat provided on a flexible substrate. In addition, the dam material is a spacer used to form a hollow portion for disposing an optical element or the like on a substrate.

The photosensitive resin composition includes the first polymer.

As the first polymer, those exemplified above can be used. The photosensitive resin composition according to the present embodiment may include one or two or more kinds selected from those exemplified as the first polymer above. The content of the first polymer in the photosensitive resin composition is not particularly limited, but is preferably equal to or greater than 20% by mass and equal to or less than 90% by mass and more preferably equal to or greater than 30% by mass and equal to or less than 80% by mass with respect to the total solid content of the photosensitive resin composition. Further, the solid content of the photosensitive resin composition indicates the content of the components excluding the solvent included in the photosensitive resin composition. Hereinafter, the same applies in the present specification.

The photosensitive resin composition may include a photosensitizer. The photosensitizer may include a diazoquinone compound. Examples of the diazoquinone compound used as a photosensitizer include compounds shown below.

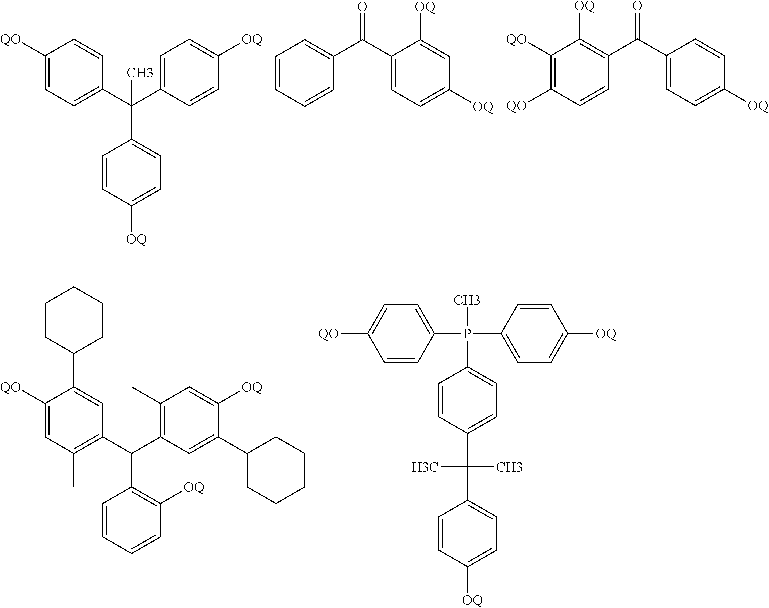

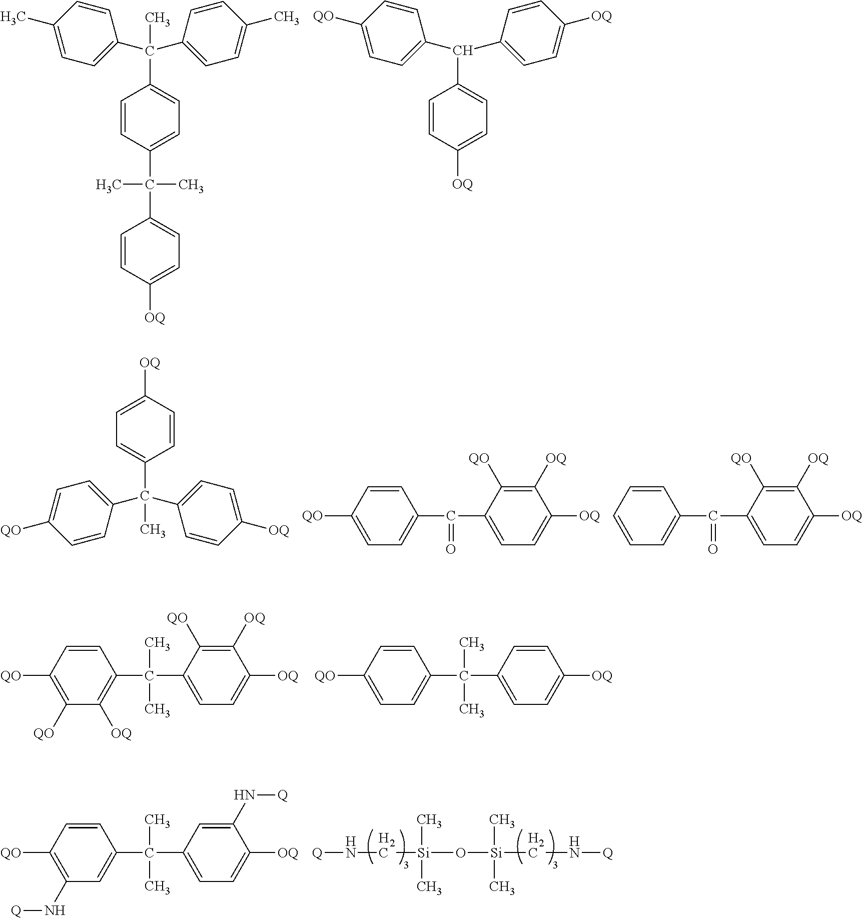

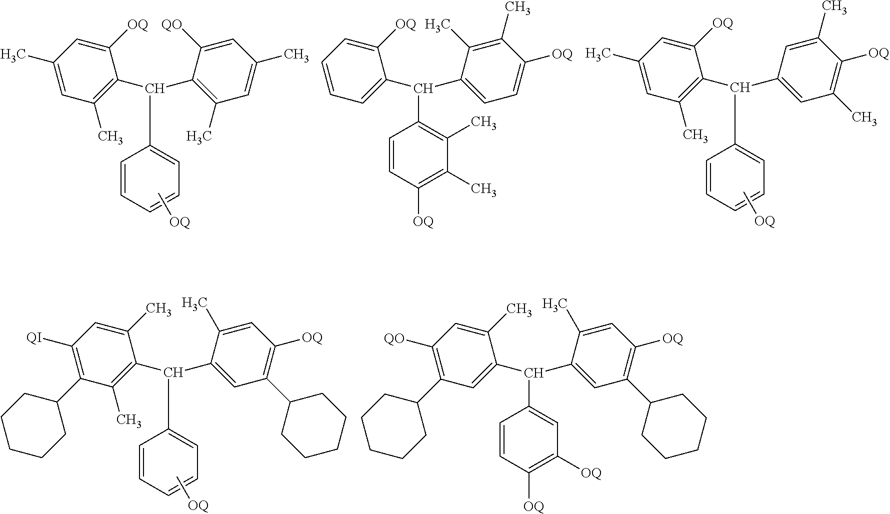

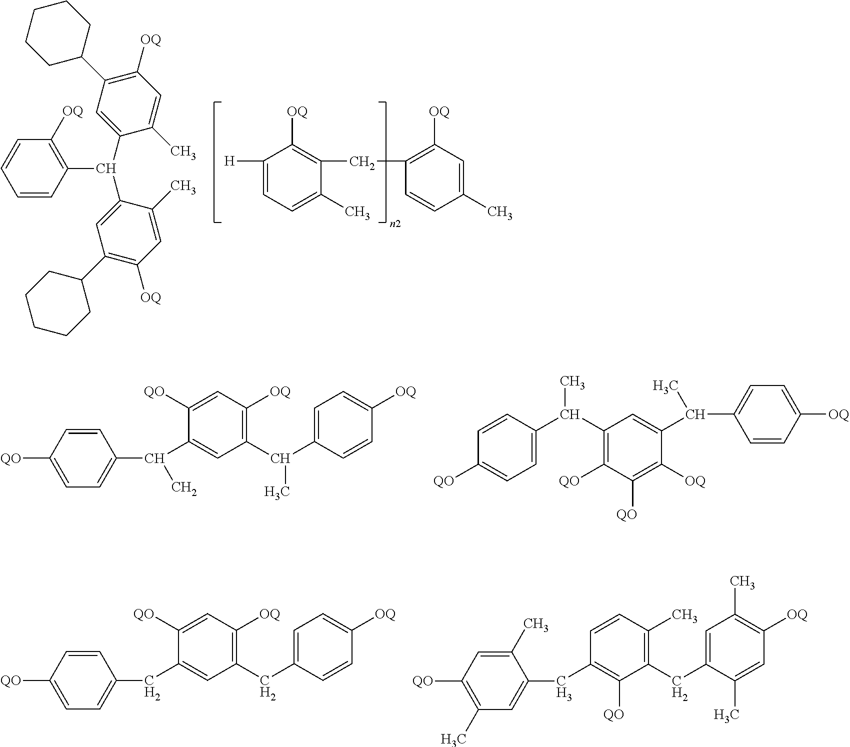

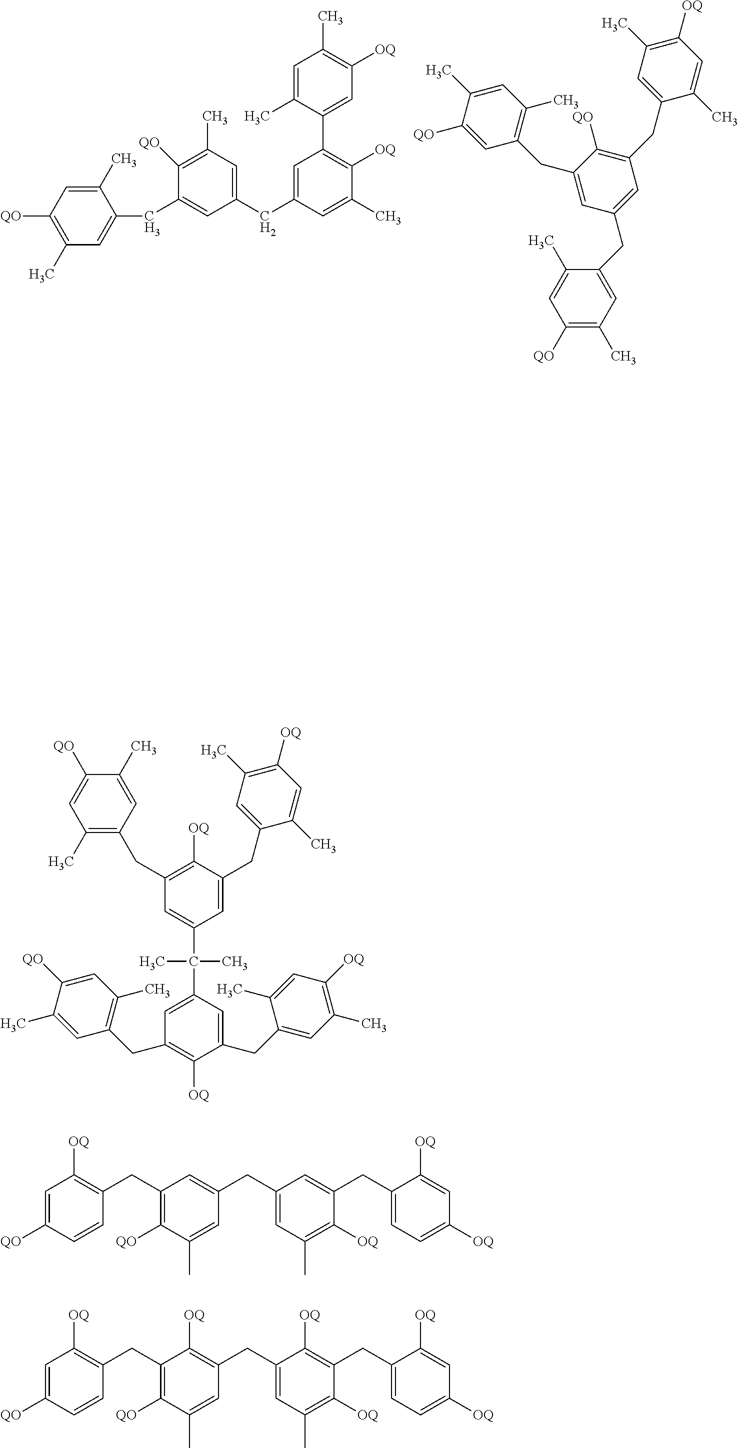

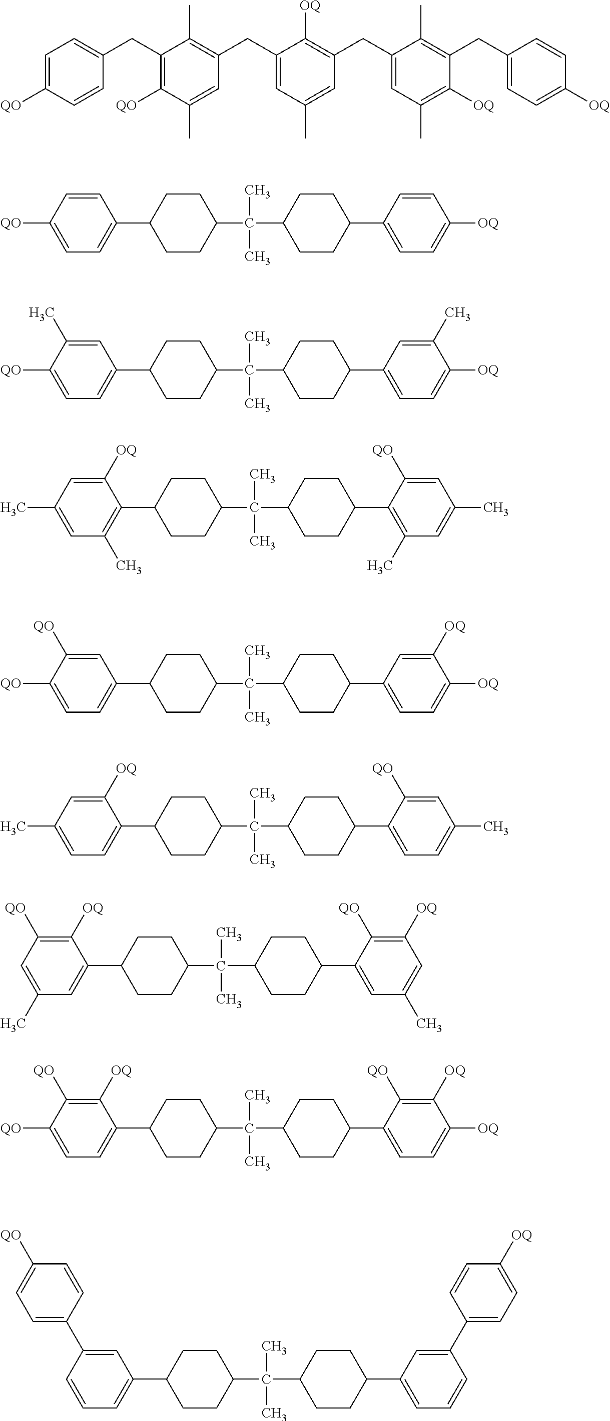

(n2 represents an integer of 1 to 5.)

In each of the above-described compounds, Q represents any of the following structure (a), structure (b), and structure (c), or a hydrogen atom. In this case, at least one Q included in the respective compounds represents any of the structure (a), the structure (b), and the structure (c). From the viewpoints of transparency and the dielectric constant of the photosensitive resin composition, an o-naphthoquinone diazide sulfonic acid derivative in which Q represents the structure (a) or the structure (b) is more preferable.

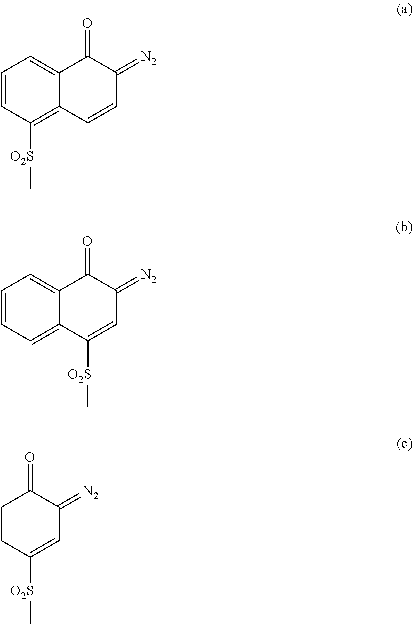

In the present embodiment, the content of the photosensitizer in the photosensitive resin composition is preferably 5% by mass or greater and more preferably 10% by mass or greater with respect to the total solid content of the photosensitive resin composition. Meanwhile, the content of the photosensitizer in the photosensitive resin composition is preferably 40% by mass or less and more preferably 30% by mass or less with respect to the total solid content of the photosensitive resin composition. When the content of the photosensitizer is adjusted to be in the above-described range, it is possible to more effectively improve the balance between the reactivity and the temporal stability of the photosensitive resin composition.

Moreover, the photosensitive resin composition may include an acid generator that generates an acid through, for example, light or heat. Examples of the photoacid that generates an acid through light include compounds, for example, sulfonium salts such as tri phenyl sulfonium trifluoromethanesulfonate, tris(4-t-butyl phenyl)sulfonium-trifluoromethanesulfonate, and diphenyl [4-(phenylthio)phenyl] sulfoniumtetrakis(pentafluorophenyl)borate; diazonium salts such as p-nitrophenyl diazonium hexafluorophosphate; ammonium salts; phosphonium salts; iodonium salts such as diphenyliodonium trifluoromethanesulfonate, and (tricumyl)iodonium-tetrakis(pentafluorophenyl)borate; quinonediazides; diazomethanes such as bis(phenylsulfonyl)diazomethane; sulfonic acid esters such as 1-phenyl-1-(4-methylphenyl)sulfonyloxy-1-benzoylmethane and N-hydroxynaphthalimide-trifluoromethanesulfonate; disulfones such as diphenyl disulfone; and triazines such as tris(2,4,6-trichloromethyl)-s-triazine, and 2-(3,4-methylenedioxyphenyl)-4,6-bis-(trichloromethyl)-s-triazine. The photosensitive resin composition of the present embodiment may include one or two or more kinds of photoacid generators exemplified above.

As the acid generator (thermal acid generator) that generates an acid through heat, the photosensitive resin composition may have aromatic sulfonium salts such as SI-45L, SI-60L, SI-80L, SI-100L, SI-110L, and SI-150L (manufactured by SANSHIN CHEMICAL INDUSTRY CO., LTD.). Moreover, in the present embodiment, the photoacid generators exemplified above and these thermal acid generators can be used in combination.

The content of the acid generator in the photosensitive resin composition is preferably equal to or greater than 0.1% by mass and equal to or less than 20% by mass and more preferably equal to or greater than 0.5% by mass and equal to or less than 10% by mass with respect to the total solid content of the photosensitive resin composition. It is thus possible to effectively improve the balance between the reactivity and the reworkability or developability of the photosensitive resin composition.

The photosensitive resin composition may include an adhesion improving agent. The adhesion improving agent is not particularly limited, and examples thereof include a silane coupling agent such as aminosilane, epoxysilane, acrylsilane, mercaptosilane, vinylsilane, ureidosilane, or sulfidesilane. These may be used alone or in combination of two or more kinds thereof. Among these, from the viewpoint of effectively improving the adhesion to other members, it is more preferable to use epoxysilane.

Examples of the aminosilane include bi s(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-β(aminoethyl)γ-aminopropyltrimethoxysilane, N-β(aminoethyl)γ-aminopropyltriethoxysilane, N-β(aminoethyl)γ-aminopropylmethyldimethoxysilane, N-β(aminoethyl)γ-aminopropylmethyldiethoxysilane, and N-phenyl-γ-amino-propyltrimethoxysilane. Examples of the epoxysilane include γ-glycidoxypropyltrimethoxysilane, γ-glycidoxypropylmethyldiethoxysilane, and β(3,4-epoxycyclohexyl)ethyltrimethoxysilane. Examples of the acrylsilane include γ-(methacryloxypropyl)trimethoxysilane, γ-(methacryloxypropyl)methyldimethoxysilane, and γ-(methacryloxypropyl)methyldiethoxysilane. Examples of the mercaptosilane include γ-mercaptopropyltrimethoxysilane. Examples of the vinylsilane include vinyltris((β-methoxyethoxy)silane, vinyltriethoxysilane, and vinyltrimethoxysilane. Examples of the ureidosilane include 3-ureidopropyltriethoxysilane. Examples of the sulfidesilane include bi s(3-(triethoxysilyl)propyl)disulfide and bi s(3-(triethoxysilyl)propyl)tetrasulfide.

The content of the adhesion improving agent in the photosensitive resin composition is preferably equal to or greater than 1% by mass and equal to or less than 10% by mass and more preferably equal to or greater than 2% by mass and equal to or less than 8% by mass with respect to the total solid content of the photosensitive resin composition. Accordingly, it is possible to more effectively improve the adhesion of a resin film, formed by the photosensitive resin composition, to other members.

The photosensitive resin composition may include a surfactant. The surfactant includes a compound including a fluorine group (such as a fluorinated alkyl group) or a silanol group, or a compound having a siloxane bond as a main skeleton. In the present embodiment, it is particularly preferable that the photosensitive resin composition includes a fluorine-based surfactant or a silicone-based surfactant as a surfactant. Examples of the surfactant include MEGAFACE F-554, MEGAFACE F-556, and MEGAFACE F-557 (manufactured by DIC Corporation), but the present invention is not limited thereto.

The content of the surfactant in the photosensitive resin composition is preferably equal to or greater than 0.1% by mass and equal to or less than 3% by mass and more preferably equal to or greater than 0.1% by mass and equal to or greater than 2% by mass with respect to the total solid content of the photosensitive resin composition. Accordingly, the flatness of the photosensitive resin composition can be effectively improved. In addition, at the time of spin-coating, it is possible to more reliably prevent the occurrence of radial striations on the coating film.

The photosensitive resin composition may include a crosslinking agent. The crosslinking agent preferably contains a compound having a heteroring as a reactive group. Among such compounds, a compound having a glycidyl group or an oxetanyl group is preferable. Among these, from the viewpoint of reactivity with a functional group having active hydrogen such as a carboxyl group or a hydroxyl group, a compound having a glycidyl group is more preferable. Examples of the compound having a glycidyl group include an epoxy compound.

Examples of the epoxy compound include glycidyl ether such as n-butyl glycidyl ether, 2-ethoxyhexyl glycidyl ether, phenyl glycidyl ether, allyl glycidyl ether, ethylene glycol diglycidyl ether, propylene glycol diglycidyl ether, neopenthyl glycol diglycidyl ether, glycerol polyglycidyl ether, sorbitol polyglycidyl ether, or glycidyl ether of bisphenol A (or F); glycidyl ester such as adipic acid diglycidyl ester or o-phthalic acid diglycidyl ester; alicyclic epoxy such as 3,4-epoxycycl ohexylmethyl(3,4-epoxycyclohexane)carboxylate, 3,4-epoxy-6-methylcyclohexylmethyl (3,4-epoxy-6-methylcyclohexane)carboxylate, bis(3,4-epoxy-6-methylcyclohexylmethyl)adipate, dicyclopentanedieneoxide, bis(2,3-epoxycyclopentyl)ether, CELLOXIDE 2021, CELLOXIDE 2081, CELLOXIDE 2083, CELLOXIDE 2085, CELLOXIDE 8000, or EPOLEAD GT401 (manufactured by Daicel Corporation); aliphatic polyglycidyl ether such as 2,2′ -(((((1-(4-(2-(4-(oxiran-2-ylmethoxy)phenyl)propan-2-yl)phenyl)ethane-1,1-diyl)bis(4,1-phe nylene)bis(oxy))bis(methylene))bis(oxirane) (such as Techmore VG3101L (manufactured by Printec Corporation)), EPOLIGHT 100MF (manufactured by KYOEISHA CHEMICAL Co., LTD.), or EPIOL TMP (manufactured by NOF CORPORATION); and 1,1,3,3,5,5-hexamethyl-1,5-bi s(3-(oxirane-2-yl•methoxy)propyl)tri•siloxane (such as DMS-E09 (manufactured by Gelest, Inc.)).

Further, other usable components include a bisphenol A type epoxy resin such as LX-01 (manufactured by DAISO CO., LTD.), jER1001, jER1002, jER1003, jER1004, jER1007, jER1009, jER1010, or jER828 (trade name, manufactured by Mitsubishi Chemical Corporation); a bisphenol F type epoxy resin such as jER807 (trade name, manufactured by Mitsubishi Chemical Corporation); a phenol novolac type epoxy resin such as jER152, jER154 (trade name, manufactured by Mitsubishi Chemical Corporation), EPPN201, or EPPN202 (trade name, manufactured by Nippon Kayaku Co., Ltd.); a cresol novolac type epoxy resin such as EOCN102, EOCN103S, EOCN104S, EOCN1020, EOCN1025, EOCN1027 (trade name, manufactured by Nippon Kayaku Co., Ltd.), or jER157S70 (trade name, manufactured by Mitsubishi Chemical Corporation); a cyclic aliphatic epoxy resin such as ARALDITE CY179, ARALDITE CY184 (trade name, manufactured by Huntsman Advanced Materials), ERL-4206, ERL-4221, ERL-4234, ERL-4299 (trade name, manufactured by Dow Chemical Company), EPICLON 200, EPICLON 400 (trade name, manufactured by DIC Corporation), jER871, or jER872 (trade name, manufactured by Mitsubishi Chemical Corporation); a polyfunctional alicyclic epoxy resin such as Poly[(2-oxiranyl)-1,2-cyclohexanediol]2-ethyl-2-(hydroxymethyl)-1,3-propanediol ether (3:1); and EHPE-3150 (manufactured by Daicel Corporation).

Moreover, the photosensitive resin composition of the present embodiment may include one or two or more kinds of epoxy compounds exemplified above.

Examples of the compound having an oxetanyl compound used as a crosslinking agent include 1,4-bis {[(3-ethyl-3-oxetanyl)methoxy]methyl }benzene, bis[ I -ethyl(3-oxetanyl)]methyl ether, 4,4′-bis[(3-ethyl-3-oxetanyl)methoxymethyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl-3-oxetanylmethyl)ether, bis(3-ethyl-3-oxetanylmethyl)diphenoate, trimethylolpropanetris(3-ethyl-3-oxetanylmethyl)ether, pentaerythritol tetrakis(3-ethyl-3-oxetanylmethyl)ether, a poly[[3-[(3-ethyl-3-oxetanyl)methoxy]propyl]silasesquioxane] derivative, oxetanyl silicate, phenol novolac type oxetane, and 1,3-bis[(3-ethyloxetan-3-yl)methoxy]benzene, but examples are not limited to these. These may be used alone or in combination of plural kinds thereof.

In the present embodiment, the content of the crosslinking agent in the photosensitive resin composition is preferably 1% by mass or greater and more preferably 5% by mass or greater with respect to the total solid content of the photosensitive resin composition. Meanwhile, the content of the crosslinking agent in the photosensitive resin composition is preferably 50% by mass or less and more preferably 40% by mass or less with respect to the total solid content of the photosensitive resin composition. When the content of the crosslinking agent is adjusted to be in the above-described range, it is possible to more effectively improve the balance between the reactivity and the temporal stability of the photosensitive resin composition.

Moreover, additives such as an antioxidant, a filler, and a sensitizer may be added to the photosensitive resin composition as needed. The photosensitive resin composition may include, as an antioxidant, one or two or more kinds selected from the group consisting of a phenolic antioxidant, a phosphorus-based antioxidant, and a thioether-based antioxidant. The photosensitive resin composition may include, as a filler, one or two or more kinds selected from inorganic fillers such as silica. The photosensitive resin composition may include, as a sensitizer, one or two or more kinds selected from the group consisting of anthracenes, xanthones, anthraquinones, phenanthrenes, chrysenes, benzopyrenes, fluoracenes, rubrenes, pyrenes, indanthrenes, and thioxanthen-9-ones.

The photosensitive resin composition may include a solvent. In this case, the photosensitive resin composition becomes varnish-like. The photosensitive resin composition may include, as a solvent, one or two or more kinds selected from propylene glycol monomethyl ether (PGME), propylene glycol monomethyl ether acetate (PGMEA), ethyl lactate, methyl isobutyl carbinol (MIBC), gamma butyrolactone (GBL), N-methylpyrrolidone (NMP), methyl n-amyl ketone (MAK), diethylene glycol monomethyl ether, diethylene glycol dimethyl ether, diethylene glycol methyl ethyl ether, and ethyl lactate. In addition, the solvent which can be used in the present embodiment is not limited to these.

It is preferable that the above-described photosensitive resin composition has physical properties described below. These physical properties can be achieved by suitably adjusting the type or the content of each component included in the photosensitive resin composition.

(1) Residual Film Rate

The residual film rate of the photosensitive resin composition after development is preferably 85% or greater. In addition, the residual film rate of the photosensitive resin composition after post-baking is preferably 80% or greater. Accordingly, a pattern having a desired shape can be achieved with an excellent precision. The upper limit of the residual film rate after development or the residual film rate after post-baking is not particularly limited, but may be set to, for example, 99%.

The residual film rate can be measured in the following manner. First, a glass substrate is spin-coated with the photosensitive resin composition and heated at 100° C. for 120 seconds using a hot plate, and a resin film obtained in this manner is referred to as a thin film A. Next, the thin film A is exposed to light at an optimum exposure amount such that the ratio of the line width to the space width of 5 μm is set to 1:1 using an exposure device, and the resultant is developed at 23° C. for 90 seconds using a 0.5 mass % tetramethylammonium hydroxide aqueous solution, thereby obtaining a thin film B. Subsequently, the entire surface of the thin film B is exposed to light using g+h+i line at 300 mJ/cm² and subjected to a post-baking treatment by heating in an oven at 230° C. for 60 minutes, thereby obtaining a thin film C. In addition, the residual film rate is calculated from the film thicknesses of the measured thin film A, thin film B, and thin film C using the following equations.

Residual film rate after development (%)=[film thickness (μm) of thin film B/film thickness (μm) of thin film A]]×100

Residual film rate after baking (%)=[film thickness (μm) of thin film C/film thickness (μm) of thin film A]]×100

(2) Relative Dielectric Constant

The relative dielectric constant of the resin film formed using the photosensitive resin composition is preferably 5.0 or less. In addition, the lower limit of the relative dielectric constant is not particularly limited, but can be set to 1.0.

The relative dielectric constant can be measured in the following manner. First, an aluminum substrate is spin-coated with the photosensitive resin composition and baked on a hot plate at 100° C. for 120 seconds. Next, the entire surface of the film is exposed to light using g+h+i line at 300 mJ/cm² and subjected to a post-baking treatment by heating in an oven at 230° C. for 60 minutes, thereby obtaining a film having a thickness of 3 μm. Thereafter, a gold electrode is formed on the film and the relative dielectric constant is measured using an LCR meter under the conditions of room temperature (25° C.) and 10 kHz.

(3) Transmittance

The light transmittance of the resin film formed using the photosensitive resin composition at a wavelength of 400 nm is preferably 80% or greater. In addition, the upper limit of the transmittance is not particularly limited, but may be set to 99%.

The transmittance can be measured, for example, in the following manner. First, a glass substrate is spin-coated with the photosensitive resin composition and baked on a hot plate at 100° C. for 120 seconds, thereby obtaining a resin film. Next, the resin film is immersed in a 0.5 wt % tetramethylammonium hydroxide aqueous solution for 90 seconds, and then rinsed with pure water. Subsequently, the entire surface of the resin film is exposed to light using g+h+i line at 300 mJ/cm² and subjected to a post-baking treatment by heating in an oven at 230° C. for 60 minutes. Further, the light transmittance of the resin film at a wavelength of 400 nm is measured using an ultraviolet-visible light spectrophotometer, and the numerical value converted into transmittance for a film thickness of 3 μm is set to the transmittance.

(4) Swelling Rate and Recovery Rate

The swelling rate of the photosensitive composition is preferably equal to or greater than 1% and equal to or less than 20%. Further, the recovery rate of the photosensitive resin composition is preferably equal to or greater than 95% and equal to or less than 105%. Accordingly, the photosensitive resin composition having excellent chemical resistance is achieved.

The swelling rate and the recovery rate can be measured in the following manner. First, a glass substrate is spin-coated with the photosensitive resin composition and pre-baked on a hot plate at 100° C. for 120 seconds, thereby obtaining a resin film. Next, the resin film is immersed in a 0.5 wt % tetramethylammonium hydroxide aqueous solution for 90 seconds, and then rinsed with pure water. Subsequently, the entire surface of the resin film is exposed to light such that the amount of integrated light of g+h+i line became 300 mJ/cm². Next, the resin film is subjected to a thermosetting treatment in an oven at 230° C. for 60 minutes. Further, the film thickness of the cured film obtained in the above-described manner (first film thickness) is measured. Subsequently, the cured film is immersed in TOK106 (manufactured by TOKYO OHKA KOGYO CO., LTD.) at 70° C. for 15 minutes, and then rinsed with pure water for 30 seconds. At this time, the film thickness obtained after rinsing the cured film is set to a second film thickness and the swelling rate is calculated from the following expression.

Swelling rate: [(second film thickness—first film thickness)/(first film thickness)]×100 (%)

Next, the cured film is heated in an oven at 230° C. for 15 minutes and the film thickness after heating (third film thickness) is measured. Further, the recovery rate is calculated from the following expression.

Recovery rate: [(third film thickness)/(first film thickness)]×100 (%)

(5) Sensitivity

The sensitivity of the photosensitive resin composition is preferably equal to or greater than 300 mJ/cm² and equal to or less than 600 mJ/cm². Accordingly, it is possible to achieve a photosensitive resin composition having excellent lithographic performance.

The sensitivity can be measured in the following manner. First, a glass substrate is spin-coated with the photosensitive resin composition and baked on a hot plate at 100° C. for 120 seconds, thereby obtaining a thin film having a thickness of approximately 3.5 μm. The thin film is exposed to light using a mask that has a hole pattern having a size of 5 μm with an exposure device. Next, a resist pattern formed by performing development using a 0.5 mass % tetramethylammonium hydroxide aqueous solution under the conditions of 23° C. for 90 seconds is observed using an SEM and the exposure amount, at which a hole pattern having a size of 5 μm² is obtained, is set to the sensitivity.

(Electronic Device)

Next, an electronic device 100 according to the present embodiment will be described.

The electronic device 100 includes an insulating film 20 which is a permanent film formed from the above-described photosensitive resin composition including the first polymer. The electronic device 100 according to the present embodiment is not particularly limited as long as the device includes an insulating layer formed from the photosensitive resin composition, and examples thereof include a display device including the insulating film 20 as a planarizing film or a micro-lens, and a semiconductor device having a multilayer wiring structure using the insulating film 20 as an interlayer insulating film.

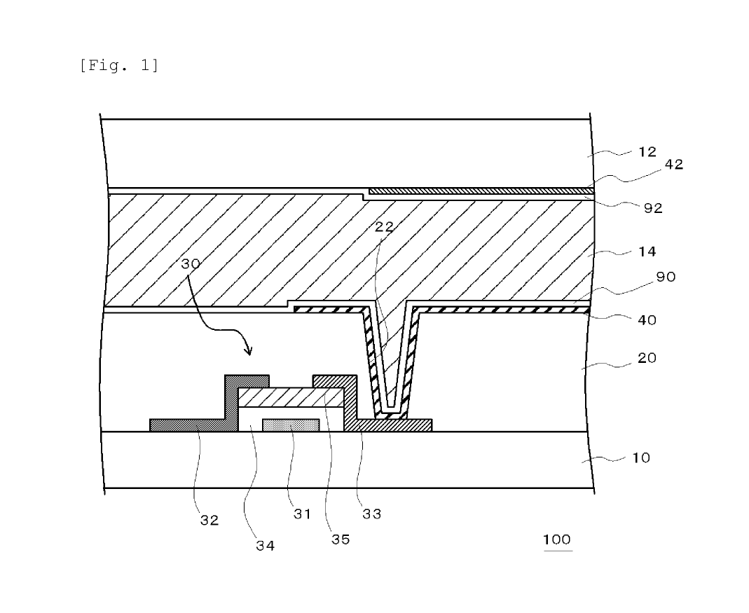

FIG. 1 is a sectional view showing an example of the electronic device 100.

FIG. 1 exemplifies a case where the electronic device 100 is used as a liquid crystal display device and the insulating film 20 is used as a planarizing film. The electronic device 100 shown in FIG. 1 includes a substrate 10, a transistor 30 provided on the substrate 10, the insulating film 20 provided on the substrate 10 such that the transistor 30 is covered, and a wiring 40 provided on the insulating film 20.

The substrate 10 is, for example, a glass substrate. The transistor 30 is, for example, a thin-film transistor constituting a switching element of a liquid crystal device. For example, a plurality of the transistors 30 are disposed in an array on the substrate 10. The transistor 30 shown in FIG. 1 is configured of, for example, a gate electrode 31, a source electrode 32, a drain electrode 33, a gate insulating film 34, and a semiconductor layer 35. The gate electrode 31 is provided, for example, on the substrate 10. The gate insulating film 34 is provided on the substrate 10 such that the gate electrode 31 is covered. The semiconductor layer 35 is provided on the gate insulating film 34. Further, the semiconductor layer 35 is, for example, a silicon layer. The source electrode 32 is provided on the substrate 10 in a state in which a part of the source electrode 32 is in contact with the semiconductor layer 35. The drain electrode 33 is provided on the substrate 10 in a state in which the drain electrode 33 is separated from the source electrode 32 and a part of the drain electrode 33 is in contact with the semiconductor layer 35.

The insulating film 20 eliminates a step caused by the transistor 30 or the like and functions as a planarizing film used to form a flat surface on the substrate 10. Further, the insulating film 20 is configured of a cured product of the above-described photosensitive resin composition. The insulating film 20 is provided with an opening 22 passing through the insulating film 20 so as to be connected with the drain electrode 33.

The wiring 40 connected with the drain electrode 33 is formed on the insulating film 20 and inside the opening 22. The wiring 40 functions as a pixel electrode constituting a pixel together with a liquid crystal.

Further, an alignment film 90 is provided on the insulating film 20 such that the wiring 40 is covered.

A counter substrate 12 facing the substrate 10 is disposed above one surface of the substrate 10 on a side on which the transistor 30 is provided. A wiring 42 is provided on one surface of the counter substrate 12 facing the substrate 10. The wiring 42 is provided in a position facing the wiring 40. Moreover, an alignment film 92 is provided on the above-described one surface of the counter substrate 12 such that the wiring 42 is covered.

The space between the substrate 10 and the counter substrate 12 is filled with liquid crystals constituting a liquid crystal layer 14.

The electronic device 100 shown in FIG. 1 can be formed in the following manner.

First, the transistor 30 is formed on the substrate 10. Next, one surface of the substrate 10, provided with the transistor 30, is coated with the photosensitive resin composition according to a printing method or a spin coating method, and the insulating film 20 covering the transistor 30 is formed. Next, the insulating film 20 is exposed to ultraviolet rays or the like, developed, and patterned. In this manner, the opening 22 is formed in a portion of the insulating film 20. Next, the insulating film 20 is heated and cured. In this manner, the insulating film 20 which is a planarizing film is formed on the substrate 10.

Next, the wiring 40 connected to the drain electrode 33 is formed inside the opening 22 of the insulating film 20. Thereafter, the counter substrate 12 is disposed on the insulating film 20 and the space between the counter substrate 12 and the insulating film 20 is filled with liquid crystals, thereby forming the liquid crystal layer 14.

Accordingly, the electronic device 100 shown in FIG. 1 is formed.

Moreover, the present invention is not limited to the above-described embodiments, and modifications and improvements can be made within the range that can achieve the object of the present invention.

### EXAMPLES

Hereinafter, examples of the present invention will be described.

### Synthesis of Monomer

### Synthesis Example

700.0 g of dicyclopentadiene and 100.0 g of liquid paraffin were injected into a reaction container equipped with a stirrer and a cooler, and a decomposition product obtained by heating the mixture in a temperature range of 160° C. to 170° C. was cooled using the cooler (cooling water temperature of 5° C.), thereby obtaining cyclopentadiene. Next, 283.2 g of acrylic oxetane (OXE-10, manufactured by OSAKA ORGANIC CHEMICAL INDUSTRY LTD.) was injected into another reaction container, 100 g of cyclopentadiene obtained above was successively added to the reaction container at a temperature of 20° C. over 3 hours, and then the mixture was stirred in a temperature range of 30° C. to 35° C. for 16 hours. Thereafter, a reaction product obtained in this manner was fractionated and purified in a vacuum distillation device using a Vigreux column, thereby obtaining a monomer represented by the following Formula (16).

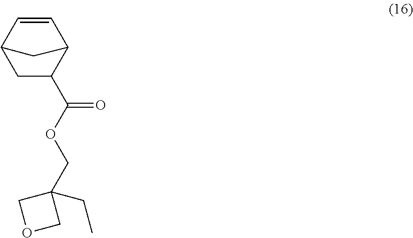 [SMILES: CCC1(COC(=O)C2CC3C=CC2C3)COC1]

It was confirmed that the obtained monomer had a structure represented by the above-described Formula (16) by analyzing a ¹H-NMR spectrum and a ¹³C-NMR spectrum. Further, the obtained monomer was a structural isomer mixture having an endo:exo ratio of 78:22. Moreover, the measured NMR spectral data was as follows.

¹H-NMR (400MHz, CDCl₃): 0.91 (t, endo-3H), 0.92 (t, exo-3H), 1.29 (d, endo-1H), 1.37-1.47 (m, 2H), 1.52 (d, exo-1H), 1.73-1.80 (m, 2H), 1.90-1.97 (m, 1H), 2.26-2.30 (m, exo-1H), 2.92 (br s, 1H), 2.98-3.03 (m, endo-1H), 3.05 (br s, exo-1H), 3.23 (s, endo-1H), 4.16 (dd, endo-2H), 4.23 (dd, exo-2H), 4.40 (d, endo-2H), 4.41 (d, exo-2H), 4.46 (d, endo-2H), 4.49 (dd, exo-2H), 5.92 (dd, endo-1H), 6.11-6.16 (m, exo-2H), 6.21 (dd, endo-1H).

¹³C-NMR (100 MHz, CDCl₃): 8.0, 26.9, 29.1, 30.3, 41.6, 42.4, 42.6, 42.6, 43.1, 43.3, 45.7, 46.3, 46.6, 49.6, 65.9, 66.2, 77.8, 77.9, 132.1, 135.6, 137.9, 138.0, 174.7, 176.2 ppm.

### Synthesis of Polymer

### Synthesis Example 1

First, the monomer (11.8 g, 50 mmol) obtained in the above-described synthesis example, maleic anhydride (2.5 g, 26.6 mmol), and N-cyclohexylmaleimide (4.5 g, 25.1 mmol) were weighed into a sealable reaction container. Further, 6.9 g of MEK in which V-601 (1.15 g, 5 mmol) was dissolved was added to the reaction container, and the mixture was stirred and dissolved. Next, after dissolved oxygen in the system was removed by nitrogen bubbling, the container was sealed and the mixture was allowed to react at 70° C. for 16 hours. Subsequently, the reaction mixture was cooled to room temperature, and 36 g of MEK was added thereto for dilution. The diluted solution was poured into a large amount of hexane, and a polymer was precipitated. The polymer was then filtered off, washed with hexane, and dried in a vacuum at 30° C. for 16 hours. At this time, the yield amount of the polymer was 16.8 g and the yield rate thereof was 90%. Subsequently, 2.0 g of the obtained polymer was dissolved in 8.0 g of MEK, and di-n-butylamine (1.5 g, 11.6 mmol) was added thereto for a reaction at 70° C. for 3 hours. Next, formic acid (1.1 g, 23.9 mmol) was added thereto for neutralization, and the resultant was washed with water 3 times so that neutralized salts were removed. A reactant obtained in this manner was poured into a large amount of hexane, and the polymer was precipitated. The polymer was then filtered off, washed with hexane, and dried in a vacuum at 30° C. for 16 hours. The yield amount of the polymer was 2.5 g. Further, the weight-average molecular weight Mw of the polymer was 6,950 and the dispersity (weight-average molecular weight Mw/number-average molecular weight Mn) thereof was 1.53.

The obtained polymer has a structure represented by the following Formula (17).

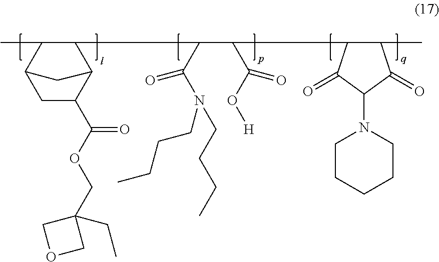

For the weight-average molecular weight (Mw) and the number-average molecular weight (Mn) of the obtained polymer, polystyrene conversion values acquired from the calibration curve of standard polystyrene (PS) obtained by GPC measurement were used. The measurement conditions are as follows.

Gel permeation chromatography device HLC-8320GPC, manufactured by Tohso Co., Ltd.

Column: TSK-GEL Supermultipore HZ-M, manufactured by Tohso Co., Ltd.

Detector: RI detector for liquid chromatogram

Measuring temperature: 40° C.

Solvent: THF

Concentration of sample: 2.0 mg/mL

Further, the same measurement conditions of the weight-average molecular weight (Mw) and the number-average molecular weight (Mn)apply to the following Synthesis Examples 2 to 4.

### Synthesis Example 2

The monomer (10.8 g, 45.8 mmol) obtained in the above-described synthesis example, norbornene carboxylic acid (11.92 g, 91.7 mmol), methyl glycidyl ether norbornene (57.6 g, 320 mmol), maleimide (28.88 g, 297.7 mmol), and N-cyclohexylmaleimide (16.32 g, 91.2 mmol) were weighed into a sealable reaction container. Further, 58.4 g of PGME in which V-601 (8.4 g, 36.5 mmol) was dissolved was added to the reaction container, and the mixture was stirred and dissolved. Next, after dissolved oxygen in the system was removed by nitrogen bubbling, the container was sealed and the mixture was allowed to react at 70° C. for 16 hours. Subsequently, the reaction mixture was cooled to room temperature, and 226 g of THF was added thereto for dilution. The diluted solution was poured into a large amount of methanol, and a polymer was precipitated. Next, the polymer was filtered off, washed with methanol, and dried in a vacuum at 30° C. for 16 hours. At this time, the yield amount of the polymer was 64.6 g and the yield rate thereof was 51%. Further, the weight-average molecular weight Mw of the polymer was 13,500 and the dispersity (weight-average molecular weight Mw/number-average molecular weight Mn) thereof was 1.71.

The obtained polymer has a structure represented by the following Formula (18).

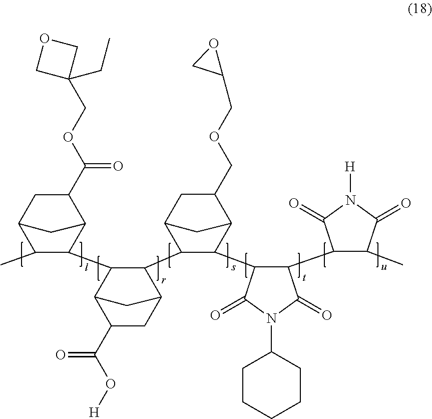

### Synthesis Example 3

The monomer (30.3 g, 128 mmol) obtained in the above-described synthesis example, maleimide (17.4 g, 179 mmol), N-cyclohexylmaleimide (13.8 g, 76.9 mmol), ethyl oxetane vinyl ether (14.5 g, 103 mmol), and butanediol monovinyl monoglycidyl ether (4.1 g, 25.6 mmol) were weighed into a reaction container equipped with a stirrer and a cooler. Further, 77.6 g of THF in which V-601 (2.36 g, 10.3 mmol) was dissolved was added to the reaction container, and the mixture was stirred and dissolved. Next, after dissolved oxygen in the system was removed by nitrogen bubbling, the mixture was held at 60° C. in a nitrogen atmosphere and allowed to react for 5 hours. Subsequently, the reaction mixture was cooled to room temperature, and 106.7 g of THF was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 61.8 g and the yield rate thereof was 77%. Further, the weight-average molecular weight Mw of the polymer was 10,330 and the dispersity (weight-average molecular weight Mw/number-average molecular weight Mn) thereof was 2.35.

The obtained polymer has a structure represented by the following Formula (19).

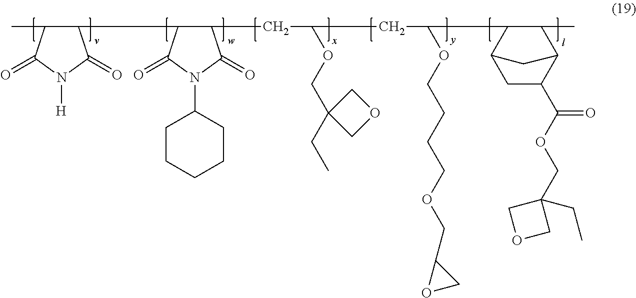

(In Formula (19), v:w:x:y:1 =35:15:20:5:25)

### Synthesis Example 4

The monomer (4.72 g, 20 mmol) obtained in the above-described synthesis example, maleimide (2.18 g, 22 mmol), N-cyclohexylmaleimide (4.92 g, 27 mmol), butanediol monovinyl monoglycidyl ether (0.79 g, 5 mmol) were weighed into a reaction container equipped with a stirrer and a cooler. Further, 9.0 g of PGME in which V-601 (0.92 g, 4 mmol) was dissolved was added to the reaction container, and the mixture was stirred and dissolved. Next, after dissolved oxygen in the system was removed by nitrogen bubbling, the mixture was held at 70° C. in a nitrogen atmosphere and allowed to react for 5 hours. Subsequently, the reaction mixture was cooled to room temperature, and 30 g of MEK was added thereto for dilution. The diluted solution was poured into a large amount of hexane, and a polymer was precipitated. Next, the polymer was filtered off, washed with hexane, and dried in a vacuum at 30° C. for 16 hours. At this time, the yield amount of the polymer was 7.5 g and the yield rate thereof was 47%. Further, the weight-average molecular weight Mw of the polymer was 16,200 and the dispersity (weight-average molecular weight Mw/number-average molecular weight Mn) thereof was 1.71.

The obtained polymer has a structure represented by the following Formula (20).

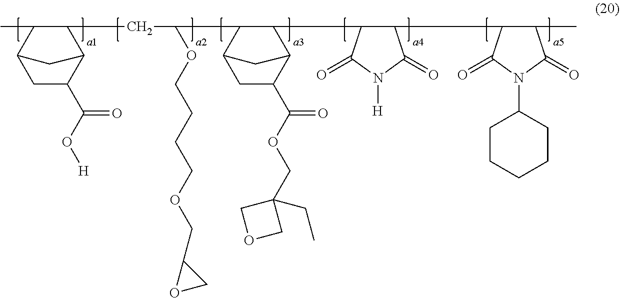

(Preparation of photosensitive resin composition)

### Example 1

10.0 g of the polymer synthesized in Synthesis Example 1, 3.0 g of an esterification product (PA-15, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 0.4 g of 1-naphthylmethylmethyl-p-hydroxyphenylsulfoniumhexafluoroantimonate (SI-60L, manufactured by SANSHIN CHEMICAL INDUSTRY CO., LTD.), 0.5 g of KBM-403 (manufactured by Shin-Etsu Silicones) for improving adhesion, and 0.1 g of F-557 (manufactured by DIC Corporation) for preventing radial striations occurring on a resist film at the time of spin-coating, were dissolved in a mixed solvent of ethyl lactate and diethylene glycol methyl ethyl ether at a mixing ratio of 70:30 such that the proportion of a solid content became 20%. This solution was filtered off using a PTFE filter having a pore size of 0.2 μm, thereby preparing a photosensitive resin composition.

### Example 2

10.0 g of the polymer synthesized in Synthesis Example 2, 2.0 g of an esterification product (PA-28, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 0.2 g of CPI-110B (manufactured by San-Apro Ltd.) as a photoacid generator, 0.5 g of KBM-403 (manufactured by Shin-Etsu Silicones) for improving adhesion, 3.0 g of CELLOXIDE 2021 (manufactured by Daicel Corporation) as an epoxy compound, and 0.1 g of F-557 (manufactured by DIC Corporation) for preventing radial striations occurring on a resist film at the time of spin-coating were dissolved in a mixed solvent of propylene glycol monomethyl ether acetate and ethylene glycol dimethyl ether at a mixing ratio of 50:50 such that the proportion of a solid content became 20%. This solution was filtered off using a PTFE filter having a pore size of 0.2 μm, thereby preparing a photosensitive resin composition.

### Example 3

A photosensitive resin composition was prepared in the same manner as in Example 1 except that the polymer synthesized in Synthesis Example 3 was used.

### Example 4

10.0 g of the polymer synthesized in Synthesis Example 4, 2.0 g of an esterification product (PA-28, manufactured by Daito Chemix Corporation) of 4,4′-(1-{4-[1(4-hydroxyphenyl)-1-methylethyl]phenyl}ethylidene)bisphenol and 1,2-naphthoquinonediazide-5-sulfonyl chloride, 0.5 g of CPI-110B (manufactured by San-Apro Ltd.) as a photoacid generator, 0.5 g of KBM-403 (manufactured by Shin-Etsu Silicones) for improving adhesion, 2.0 g of CELLOXIDE 2081 (manufactured by Daicel Corporation) as an epoxy compound, and 0.05 g of F-557 (manufactured by DIC Corporation) for preventing radial striations occurring on a resist film at the time of spin-coating were dissolved in a mixed solvent of propylene glycol monomethyl ether acetate and ethylene glycol dimethyl ether at a mixing ratio of 50:50 such that the proportion of a solid content became 20%. This solution was filtered off using a PTFE filter having a pore size of 0.2 μm, thereby preparing a photosensitive resin composition.

(Formation of Thin Film Pattern)

In each of the examples, a thin film pattern was formed in the following manner. First, a Corning 1737 glass substrate having a length of 100 mm and a width of 100 mm (manufactured by Corning Incorporated) was spin-coated (rotation speed of 300 rpm to 2500 rpm) with the obtained photosensitive resin composition and baked at 100° C. for 120 seconds using a hot plate, thereby obtaining a thin film A having a thickness of approximately 3.5 μm. Next, the thin film A was exposed to light at an optimum exposure amount such that the ratio of the line width to the space width of 5 μm was set to 1:1 using a g+h+i line mask aligner (PLA-501F, manufactured by Canon Inc.), and the resultant was developed at 23° C. for 90 seconds using a 0.5 mass % tetramethylammonium hydroxide aqueous solution, thereby obtaining a thin film B provided with a pattern having a ratio of the line width to the space width of 1:1. Subsequently, the entire surface of the thin film B was exposed to light using PLA-501F at 300 mJ/cm² and subjected to a post-baking treatment by heating in an oven at 230° C. for 60 minutes, thereby obtaining a patterned thin film C having a thickness of approximately 3.0 μm.

(Evaluation of Residual Film Rate after Development and Post-Baking)

In each of the examples, the residual film rate was calculated using the following equations from the film thicknesses of the thin film A, the thin film B, and the thin film C obtained by forming the above-described thin film pattern.

Residual film rate after development (%)=[film thickness (μm) of thin film B/film thickness (μm) of thin film A]]×100

Residual film rate after post-baking (%)=[film thickness (μm) of thin film C/film thickness (μm) of thin film A]]×100

(Evaluation of Developability)

In each of the examples, the 5 μm-sized pattern of the thin film B obtained by forming the above-described thin film pattern was observed using a scanning electron microscope (SEM). The developability was evaluated as “poor” when residues were seen in a space portion and “good” when residues were not seen in a space portion.

(Evaluation of Relative Dielectric Constant)

In each of the examples, a thin film having a thickness of 3.0 μm without a pattern was obtained on an aluminum substrate by performing the same operation as the operation for forming the above-described thin film pattern except that a test pattern was not exposed to light or developed using PLA-501F and an aluminum substrate was used as a substrate. Thereafter, a gold electrode was formed on this thin film and the relative dielectric constant was calculated from the electrostatic capacity obtained using an LCR meter (4282A, manufactured by Hewlett-Packard Company) under the conditions of room temperature (25° C.) and 10 kHz.

(Evaluation of Transmittance)

In each of the examples, a thin film without a pattern was obtained on a glass substrate by performing the same operation as the operation for forming the above-described thin film pattern except that a test pattern was not exposed to light. Further, the light transmittance (%) of the thin film at a wavelength of 400 nm was measured using an ultraviolet-visible light spectrophotometer, and the numerical value converted into transmittance for a film thickness of 3 μm was set to the transmittance.

(Evaluation of Chemical Resistance)

In each of the examples, the swelling rate and the recovery rate were measured in the following manner. First, a Corning 1737 glass substrate having a length of 100 mm and a width of 100 mm (manufactured by Corning Incorporated) was spin-coated with the obtained photosensitive resin composition and pre-baked at 100° C. for 120 seconds using a hot plate, thereby obtaining a resin film having a thickness of approximately 3.5 μm. Next, the resin film was immersed in a developer (0.5 wt % TMAH) for 90 seconds, and then rinsed with pure water. Next, the entire surface of the resin film was exposed to light such that the amount of integrated light of g+h+i line became 300 mJ/cm² using a g+h+i line mask aligner (PLA-501F (ultra-high pressure mercury lamp), manufactured by Canon Inc.). Next, the resin film was subjected to a thermosetting treatment in an oven at 230° C. for 60 minutes. Subsequently, the film thickness of the obtained cured film (first film thickness) was measured. The cured film was thereafter immersed in TOK106 (manufactured by TOKYO OHKA KOGYO CO., LTD.) at 70° C. for 15 minutes, and then rinsed with pure water for 30 seconds. At this time, the film thickness obtained after the cured film was rinsed was set to a second film thickness and the swelling rate was calculated from the following expression.

Swelling rate: [(second film thickness−first film thickness)/(first film thickness)]×100 (%)

Next, the cured film was heated in an oven at 230° C. for 15 minutes and the film thickness after heating (third film thickness) was measured. Further, the recovery rate was calculated from the following expression.

Recovery rate: [(third film thickness)/(first film thickness)]×100 (%)

(Sensitivity)

In each of the examples, the sensitivity was measured in the following manner. First, a Corning 1737 glass substrate having a length of 100 mm and a width of 100 mm (manufactured by Corning Incorporated) was spin-coated with the obtained photosensitive resin composition and baked at 100° C. for 120 seconds using a hot plate, thereby obtaining a thin film A having a thickness of approximately 3.5 μm. Next, the thin film A was exposed to light using a mask having a hole pattern having a size of 5 μm with a g+h+i line mask aligner (PLA-501F, manufactured by Canon Inc.). Next, a resist pattern formed by performing development using a 0.5 mass % tetramethylammonium hydroxide aqueous solution under the conditions of 23° C. for 90 seconds was observed using an SEM, and the exposure amount (mJ/cm²), at which a hole pattern having a size of 5 μm² was obtained, was set to the sensitivity.

(Reworkability)

In Examples 1 to 4, the reworkability of the photosensitive resin composition was evaluated in the following manner.

First, a Corning 1737 glass substrate having a length of 100 mm and a width of 100 mm (manufactured by Corning Incorporated) was spin-coated (rotation speed of 500 rpm to 2500 rpm) with the obtained photosensitive resin composition and pre-baked at 100° C. for 120 seconds using a hot plate, thereby obtaining a resin film having a thickness of approximately 3.0 μm. Next, the resin film was exposed to light such that the amount of integrated light of g+h+i line became 300 mJ/cm² using a g+h+i line mask aligner (PLA-501F (ultra-high pressure mercury lamp), manufactured by Canon Inc.) and a mask having a mask pattern of a size of 5 μm. Next, the resin film was subjected to a development treatment using a 0.5% tetramethylammonium hydroxide aqueous solution and rinsed with pure water, thereby obtaining a thin film provided with a pattern. This thin film was subjected to a bleach treatment without using a mask such that the amount of integrated light of g+h+i line became 300 mJ/cm². Subsequently, after the resin film was allowed to stand for 24 hours in a yellow room (using a HEPA filter) in which the temperature and the humidity were respectively maintained to 23±1° C. and 40±5%, the resin film was subjected to a bleach treatment again without using a mask such that the amount of integrated light of g+h+i line became 300 mJ/cm². Next, the resin film was immersed in a 2.38% tetramethylammonium hydroxide (TMAH) aqueous solution at a temperature of 23±1° C. for 120 seconds. At this time, the presence or absence of residues of the resin film on the substrate was observed using a microscope. The reworkability was evaluated as “good” when residues of the resin film were not observed and “poor” when residues of the resin film were observed.

TABLE 1

| | | | Example 1 | Example 2 | Example 3 | Example 4 |
|---|---|---|---|---|---|---|
| Photosensitive resin | Polymer | Synthesis | 10.0(71.4) | | | |
| composition | | Example 1 | | | | |
| | | Synthesis | | 10.0(63.3) | | |
| | | Example 2 | | | | |
| | | Synthesis | | | 10.0(71.4) | |
| | | Example 3 | | | | |
| | | Synthesis | | | | 10.0(66.4) |
| | | Example 4 | | | | |

| | | | | |
|---|---|---|---|---|
| PA-15 | 3.0(21.4) | | 3.0(21.4) | |
| PA-28 | | 2.0(12.7) | | 2.0(13.3) |
| CELLOXIDE | | 3.0(19.0) | | 2.0(13.3) |
| SI-60L | 0.4(2.9) | | 0.4(2.9) | |
| CPI-110B | | 0.2(1.3) | | 0.5(3.3) |
| KBM-403 | 0.5(3.6) | 0.5(3.2) | 0.5(3.6) | 0.5(3.3) |
| F-557 | 0.1(0.7) | 0.1(0.6) | 0.1(0.7) | 0.05(0.3) |

| | | | | |
|---|---|---|---|---|
| Residual film rate after development (%) | 90 | 95 | 87 | 93 |
| Residual film rate after post-baking (%) | 81 | 88 | 81 | 86 |
| Developability | Good | Good | Good | Good |
| Relative dielectric constant | 3.5 | 3.6 | 3.7 | 3.6 |
| Transmittance (%) | 85 | 92 | 87 | 90 |
| Swelling rate (%) | 7 | 5 | 9 | 7 |
| Recovery rate (%) | 100 | 100 | 99 | 103 |
| Sensitivity (mJ/cm²) | 400 | 420 | 450 | 400 |
| Reworkability | Good | Good | Good | Good |

In Table 1, of the numerical values showing blending amounts of respective components included in the photosensitive resin composition, the numerical values before the parentheses represent the mass (g) of each component and the numerical values in the parentheses represent the blending ratio (% by mass) of each component when the total solid content of the resin composition (that is, components from which a solvent is excluded) was set to 100% by mass.

This application claims priority based on Japanese Patent application No. 2014-058123, filed on Mar. 20, 2014, the entire disclosure of which is incorporated herein.

1. A polymer comprising:
a structural unit represented by the following Formula (1a); and
a structural unit represented by the following Formula (1b): 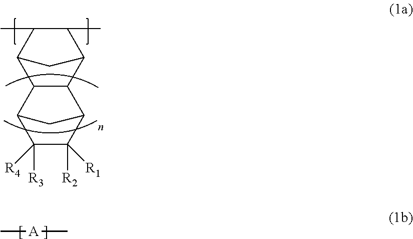
wherein in Formula (1a), n represents 0, 1, or 2, and R₁, R₂, R₃, and R₄ each independently represent hydrogen or an organic group having 1 to 10 carbon atoms, at least one of R₁, R₂, R₃, and R₄ including an oxetane ring, and A represents a structural unit represented by the following Formula (3), (4), (5), or (6): 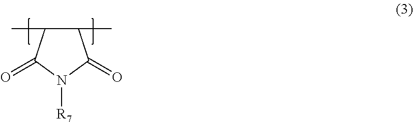
wherein in Formula (3), R₇ represents hydrogen, an alkyl group having 1 to 12 carbon atoms, or a cycloalkyl group having 3 to 8 carbon atoms, 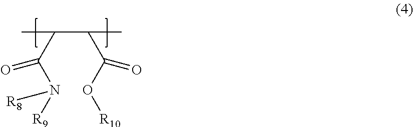
in Formula (4), R₈, R₉, and R₁₀ each independently represent hydrogen, an alkyl group having 1 to 12 carbon atoms, or a cycloalkyl group having 3 to 8 carbon atoms, 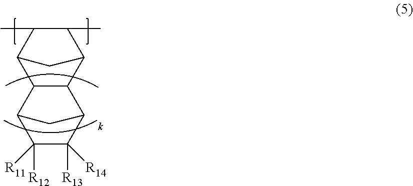
in Formula (5), k represents 0, 1, or 2, and R₁₁, R₁₂, R₁₃, and R₁₄ each independently represent hydrogen or an organic group having 1 to 10 carbon atoms, 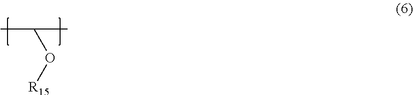
and in Formula (6), R₁₅ represents an organic group having 1 to 10 carbon atoms.

2. The polymer according to claim 1,
wherein at least one of R₁, R₂, R₃, and R₄ represents an organic group represented by the following Formula (7), and
the rest represents hydrogen: 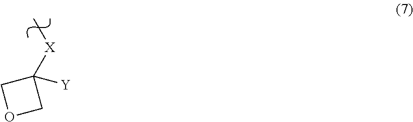
wherein in Formula (7), X represents a single bond or a divalent organic group having 1 to 6 carbon atoms, and Y represents hydrogen or an alkyl group having 1 to 7 carbon atoms.

3. The polymer according to claim 2,
wherein at least one of R₁, R₂, R₃, and R₄ represents an organic group represented by the following Formula (8), and
the rest represents hydrogen:

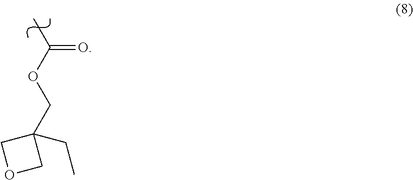

4. The polymer according to claim 2,
wherein any one of R₁, R₂, R₃, and R₄ represents an organic group represented by the following Formula (9), and
the rest represents hydrogen:

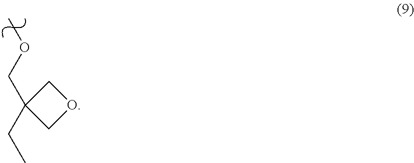

5. A photosensitive resin composition which is used for forming a permanent film, the composition comprising:
the polymer according to claim 1.

6. An electronic device comprising:
a permanent film formed from the photosensitive resin composition according to claim 5.
